(19) United States
(12) Patent Application Publication
(10) Pub. No.: US 2023/0261129 A1
(43) Pub. Date: Aug. 17, 2023

(54) PHOTOVOLTAIC CELL DEVICE

(71) Applicants: Japan Display Inc., Tokyo (JP); OSAKA UNIVERSITY, Suita-shi (JP)

(72) Inventors: Shinichiro OKA, Tokyo (JP); Yasushi TOMIOKA, Tokyo (JP); Junji KOBASHI, Tokyo (JP); Hiroyuki YOSHIDA, Osaka (JP)

(73) Assignees: Japan Display Inc., Tokyo (JP); OSAKA UNIVERSITY, Suita-shi (JP)

(21) Appl. No.: 18/304,968

(22) Filed: Apr. 21, 2023

Related U.S. Application Data
(63) Continuation of application No. PCT/JP2021/025456, filed on Jul. 6, 2021.

(30) Foreign Application Priority Data
Oct. 22, 2020 (JP) 2020-177509

(51) Int. Cl. H01L 31/054; G02B 1/14; G02B 5/20; G02B 6/42

(52) U.S. Cl. CPC H01L 31/0547; G02B 1/14; G02B 5/208; G02B 6/42; G02B 6/4214

(57) ABSTRACT

According to one embodiment, a photovoltaic cell device includes an optical waveguide including a first main surface, a second main surface opposed to the first main surface, and a side surface, an optical element opposed to the second main surface, containing cholesteric liquid crystal, and reflecting at least a part of incident light via the optical waveguide toward the optical waveguide, a photovoltaic cell opposed to the side surface, and a protective film, and the protective film is provided to be in contact with the first main surface.

### CROSS-REFERENCE TO RELATED APPLICATIONS

This application is a Continuation application of PCT Application No. PCT/JP2021/025456, filed Jul. 6, 2021 and based upon and claiming the benefit of priority from Japanese Patent Application No. 2020-177509, filed Oct. 22, 2020, the entire contents of all of which are incorporated herein by reference.

### FIELD

Embodiments described herein relate generally to a photovoltaic cell device.

### BACKGROUND

In recent years, various transparent photovoltaic cells have been proposed. For example, a display device with a photovoltaic cell in which a transparent dye-sensitized photovoltaic cell is arranged on the surface of the display device has been proposed.

There is a demand for improving reliability in photovoltaic cell devices.

### BRIEF DESCRIPTION OF THE DRAWINGS

FIG. 1 is a cross-sectional view schematically showing a photovoltaic cell device 100 according to Embodiment 1.

FIG. 2 is a cross-sectional view schematically showing a structure of the optical element 3.

FIG. 3 is a plan view schematically showing the photovoltaic cell device 100.

FIG. 4 is a cross-sectional view schematically showing a photovoltaic cell device 100 according to Embodiment 2.

FIG. 5 is a cross-sectional view schematically showing a photovoltaic cell device 100 according to Embodiment 3.

FIG. 6 is a cross-sectional view schematically showing a photovoltaic cell device 100 according to Embodiment 4.

FIG. 7 is a cross-sectional view schematically showing a photovoltaic cell device 100 according to Embodiment 5.

FIG. 8 is a cross-sectional view schematically showing a photovoltaic cell device 100 according to Embodiment 6.

FIG. 9 is a cross-sectional view schematically showing a photovoltaic cell device 100 according to Embodiment 7.

FIG. 10 is a cross-sectional view schematically showing the optical element 3 according to a modified example.

### DETAILED DESCRIPTION

Embodiments described herein aim to provide a photovoltaic cell device capable of improving the reliability.

In general, according to one embodiment, a photovoltaic cell device comprises: an optical waveguide including a first main surface, a second main surface opposed to the first main surface, and a side surface; an optical element opposed to the second main surface, containing cholesteric liquid crystal, and reflecting at least a part of incident light via the optical waveguide toward the optical waveguide; a photovoltaic cell opposed to the side surface; and a protective film. The protective film is provided to be in contact with the first main surface.

According to another embodiment, a photovoltaic cell device comprises: an optical waveguide including a first main surface, a second main surface opposed to the first main surface, and a side surface; an optical element opposed to the second main surface, containing cholesteric liquid crystal, and reflecting at least a part of incident light via the optical waveguide toward the optical waveguide; a photovoltaic cell opposed to the side surface; and a protective film. The protective film is provided at a position opposed to the optical element.

According to an embodiment, a photovoltaic cell device capable of improving the reliability can be provided.

Embodiments will be described hereinafter with reference to the accompanying drawings. The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes and the like, of the respective parts are illustrated schematically in the drawings, rather than as an accurate representation of what is implemented. However, such schematic illustration is merely exemplary, and in no way restricts the interpretation of the invention. In addition, in the specification and drawings, the same elements as those described in connection with preceding drawings are denoted by like reference numbers, and detailed description thereof is omitted unless necessary.

In the drawings, an X-axis, a Y-axis and a Z-axis orthogonal to each other are described in the drawings to facilitate understanding as needed. A direction along the Z-axis is referred to as a Z-direction or a first direction A1, a direction along the Y-axis is referred to as a Y-direction or a second direction A2, and a direction along the X-axis is referred to as an X-direction or a third direction A3. A plane defined by the X-axis and the Y-axis is referred to as an X-Y plane, a plane defined by the X-axis and Z-axis is referred to as a X-Z plane, and a plane defined by the Y-axis and Z-axis is referred to as a Y-Z plane.

### Embodiment 1

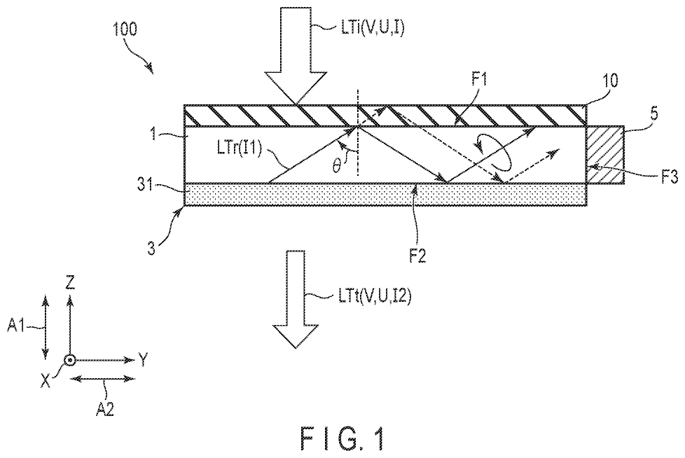

FIG. 1 is a cross-sectional view schematically showing a photovoltaic cell device 100 according to Embodiment 1. The photovoltaic cell device 100 comprises an optical waveguide 1, an optical element 3, a photovoltaic cell 5, and a protective film 10.

The optical waveguide 1 is made of a transparent member that transmits light, for example, a transparent glass plate or a transparent synthetic resin plate. The optical waveguide 1 may be made of, for example, a flexible transparent synthetic resin plate. The optical waveguide 1 can be formed in any shape. For example, the optical waveguide 1 may be curved. A refractive index of the optical waveguide 1 is, for example, larger than the refractive index of air. The optical waveguide 1 functions as, for example, a window glass.

In this specification, “light” includes visible light and invisible light. For example, a lower limit wavelength of the visible light range is 360 nm or more and 400 nm or less, and an upper limit wavelength of the visible light range is 760 nm or more and 830 nm or less. The visible light includes a first component (blue component) in a first wavelength range (for example, 400 nm to 500 nm), a second component (green component) in a second wavelength range (for example, 500 nm to 600 nm), and a third component (red component) in a third wavelength range (for example, 600 nm to 700 nm). The invisible light includes an ultraviolet ray in a wavelength range shorter than the first wavelength range and an infrared ray in a wavelength range longer than the third wavelength range.

In this specification, “transparent” is preferably colorless and transparent. However, “transparent” may be translucent or colored transparent.

The optical waveguide 1 is formed in a flat plate shape along an X-Y plane, and includes a first main surface F1, a second main surface F2, and a side surface F3. The first main surface F1 and the second main surface F2 are planes substantially parallel to the X-Y plane and are opposed to each other in the first direction A1. The side surface F3 is a plane extending along the first direction A1. In the example shown in FIG. 1, the side surface F3 is a plane substantially parallel to the X-Z plane, but the side surface F3 includes a plane substantially parallel to the Y-Z plane.

The optical element 3 is opposed to the second main surface F2 of the optical waveguide 1, in the first direction A1. The optical element 3 reflects at least a part of incident light LTi from the first main surface F1 side toward the optical waveguide 1. In one example, the optical element 3 comprises a liquid crystal layer 31 which reflects at least one of first circularly polarized light and second circularly polarized light turned in a direction opposite to the first circularly polarized light, of the incident light LTi via the optical waveguide 1. The first circularly polarized light and the second circularly polarized light reflected by the optical element 3 are, for example, infrared light, but may be visible light. Incidentally, in this specification, “reflection” in the optical element 3 is accompanied by diffraction inside the optical element 3.

For example, the optical element 3 may have flexibility. Alternatively, the optical element 3 may be in contact with the second main surface F2 of the optical waveguide 1 or a transparent layer such as an adhesive layer or the like may be interposed between the optical element 3 and the optical waveguide 1. The refractive index of the layer interposed between the optical element 3 and the optical waveguide 1 is, desirably, substantially equivalent to the refractive index of the optical waveguide 1.

The optical element 3 is composed as a thin film. For example, the optical element 3 formed in a film shape separately may be bonded to the optical waveguide 1 or the material may be directly applied to the optical waveguide 1 to form the film-shaped optical element 3.

The photovoltaic cell 5 is opposed to the side surface F3 of the optical waveguide 1 in the second direction A2. The photovoltaic cell 5 receives light and converts the energy of the received light into electric power. In other words, the photovoltaic cell 5 generates electricity by the received light. The type of the photovoltaic cell is not particularly limited, and the photovoltaic cell 5 is, for example, a silicon-based photovoltaic cell, a compound photovoltaic cell, an organic photovoltaic cell, a perovskite-type photovoltaic cell, or a quantum dot-type photovoltaic cell. The silicon-based photovoltaic cells include photovoltaic cell comprising amorphous silicon, photovoltaic cell comprising polycrystalline silicon, and the like. The photovoltaic cell 5 described here is an example of a photoreceiver. Another example of the photoreceiver is an optical sensor. In other words, the photovoltaic cell 5 may be replaced with the optical sensor.

When the photovoltaic cell 5 is a silicon-based photovoltaic cell, the photovoltaic cell 5 comprises polycrystalline silicon in one example. The peak absorption wavelength of the polycrystalline silicon is approximately 700 nm. In other words, the polycrystalline silicon has a high absorption index of the infrared ray. For this reason, the photovoltaic cell 5 is suitable for power generation using the infrared ray.

The protective film 10 is opposed to the first main surface F1 of the optical waveguide 1 in the first direction A1. In particular, in Embodiment 1, the protective film 10 is in contact with the first main surface F1. Such a protective film 10 is transparent and, in particular, has optical transparency to the visible light and to the infrared ray used for power generation. The refractive index of the protective film 10 is substantially equivalent to the refractive index of the optical waveguide 1.

Next, the operation of the photovoltaic cell device 100 in Embodiment 1 shown in FIG. 1 will be described.

The incident light LTi on the photovoltaic cell device 100 is, for example, solar light. In other words, the light LTi includes the ultraviolet ray U and the infrared ray I in addition to the visible light V.

In the example shown in FIG. 1, the light LTi is assumed to be made incident substantially perpendicularly to the optical waveguide 1 via the protective film 10 to facilitate the understanding. Incidentally, the incidence angle of the light LTi on the optical waveguide 1 is not particularly limited. For example, the light LTi may be made incident on the optical waveguide 1 at a plurality of incidence angles different from each other.

The light LTi enters the inside of the optical waveguide 1 from the first main surface F1 via the protective film 10, exits from the second main surface F2, and is made incident on the optical element 3. Then, the optical element 3 reflects a part of light LTr of the light LTi toward the optical waveguide 1 and the photovoltaic cell 5, and transmits the other light LTt. Here, optical loss such as absorption in the optical waveguide 1 and the optical element 3 is ignored. The light LTr reflected by the optical element 3 corresponds to, for example, the first circularly polarized light of a predetermined wavelength. In addition, the light LTt transmitted through the optical element 3 includes the second circularly polarized light of the predetermined wavelength and light of a wavelength different from the predetermined wavelength. The predetermined wavelength is, for example, the infrared ray I, and the light LTr reflected by the optical element 3 is the first circularly polarized light I1 of the infrared ray I. The light LTt includes the visible light V, the ultraviolet ray U, and the second circularly polarized light I2 of the infrared ray I. Incidentally, in this specification, the circularly polarized light may be strictly circularly polarized light or circularly polarized light similar to elliptically polarized light.

The optical element 3 reflects the first circularly polarized light I1 toward the optical waveguide 1, at an approach angle θ that satisfies the optical waveguide conditions in the optical waveguide 1. The approach angle θ corresponds to an angle equal to or higher than a critical angle θc that causes total reflection inside the optical waveguide 1. The approach angle θ indicates an angle to a perpendicular line orthogonal to the optical waveguide 1.

The optical LTr enters the inside of the optical waveguide 1 from the second main surface F2, and propagates inside the optical waveguide 1 while repeating reflection in the optical waveguide 1.

Incidentally, when the optical waveguide 1 and the protective film 10 have the equivalent refractive indexes as described above, the optical waveguide 1 and the protective film 10 can be a single optical waveguide structure. In this case, the light LTr that has entered the inside of the optical waveguide 1 propagates while repeating reflection at an interface between the protective film 10 and air, as represented by an arrow of a dotted line.

The photovoltaic cell 5 receives the light LTr emitted from the side surface F3 to generate electricity.

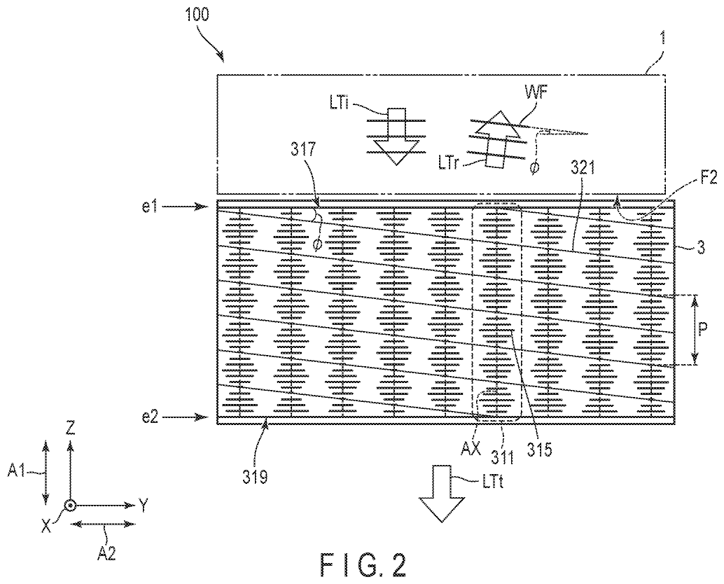

FIG. 2 is a cross-sectional view schematically showing a structure of the optical element 3. Incidentally, the optical waveguide 1 is represented by a two-dot chain line.

The optical element 3 includes a plurality of helical structures 311. Each of the plurality of helical structures 311 extends along the first direction A1. In other words, a helical axis AX of each of the plurality of helical structures 311 is substantially perpendicular to the second main surface F2 of the optical waveguide 1. The helical axis AX is substantially parallel to the first direction A1. Each of the plurality of helical structures 311 have a helical pitch P. The helical pitch P indicates one cycle (360 degrees) of the spiral. Each of the plurality of helical structures 311 includes a plurality of elements 315. The plurality of elements 315 are helically stacked along the first direction A1 while turning.

The optical element 3 has a first boundary surface 317 opposed to the second main surface F2, a second boundary surface 319 on a side opposite to the first boundary surface 317, and a plurality of reflective surfaces 321 between the first boundary surface 317 and the second boundary surface 319. The first boundary surface 317 is a surface on which the light LTi transmitted through the optical waveguide 1 is made incident on the optical element 3. Each of the first boundary surface 317 and the second boundary surface 319 is substantially perpendicular to the helical axis AX of the helical structure 311. Each of the first boundary surface 317 and the second boundary surface 319 is substantially parallel to the optical waveguide 1 (or the second main surface F2).

The first boundary surface 317 includes an element 315 located at one end e1 of both ends of the helical structure 311. The first boundary surface 317 is located at the boundary between the optical waveguide 1 and the optical element 3. The second boundary surface 319 includes an element 315 located at the other end e2 of both ends of the helical structure 311. The second boundary surface 319 is located at the boundary between the optical element 3 and air.

In the example shown in FIG. 2, the plurality of reflective surfaces 321 are substantially parallel to each other. The reflective surface 321 is inclined to the first boundary surface 317 and the optical waveguide 1 (or the second main surface F2) and has a substantially planar shape extending in a constant direction. The reflective surface 321 selectively reflects partial light LTr of the light LTi made incident from the first boundary surface 317, according to Bragg's law. More specifically, the reflective surface 321 reflects the light LTr such that a wavefront WF of the light LTr is substantially parallel to the reflective surface 321. Furthermore, the reflective surface 321 reflects the light LTr according to the inclination angle φ of the reflective surface 321 to the first boundary surface 317.

The reflective surface 321 can be defined as follows. That is, the refractive index felt by the light of a predetermined wavelength (for example, circularly polarized light) selectively reflected by the optical element 3 gradually changes as the light travels inside the optical element 3. For this reason, Fresnel reflection gradually occurs in the optical element 3. Then, Fresnel reflection occurs most strongly at the position where the refractive index felt by the light changes most in the plurality of helical structures 311. In other words, the reflective surface 321 corresponds to a surface where Fresnel reflection occurs most strongly in the optical element 3.

The alignment directions of the respective elements 315 in the helical structures 311 adjacent to the second direction A2, among the plurality of helical structures 311, are different from each other. In addition, the spatial phases of the respective helical structures 311 adjacent to the second direction A2, among the plurality of helical structures 311, are different from each other. The reflective surface 321 corresponds to a surface in which the alignment directions of the elements 315 are approximately coincident with each other or a surface in which the spatial phases are approximately coincident with each other (equiphase wave surfaces). In other words, each of the plurality of reflective surfaces 321 is inclined to the first boundary surface 317 or the optical waveguide 1.

Incidentally, the shape of the reflective surface 321 is not limited to the planar shape as shown in FIG. 2, but may be a concave or convex curved surface shape, and is not particularly limited. In addition, a part of the reflective surface 321 may have unevenness, the inclination angle φ of the reflective surface 321 may not be uniform, or the plurality of reflective surfaces 321 may not be regularly aligned. The reflective surfaces 321 of any shapes can be constituted in accordance with the spatial phase distribution of the plurality of helical structures 311.

In the present embodiment, each of the helical structures 311 is cholesteric liquid crystal. Each of the elements 315 corresponds to a liquid crystal molecule. To simplify the illustration, in FIG. 2, one element 315 represents a liquid crystal molecule facing in the average alignment direction, of the plurality of liquid crystal molecules located in the X-Y plane.

The cholesteric liquid crystal which is the helical structure 311 reflects circularly polarized light in the same turning direction as the turning direction of the cholesteric liquid crystal, of the light of a predetermined wavelength λ included in the selective reflection range Δλ. For example, when the turning direction of the cholesteric liquid crystal is clockwise, the cholesteric liquid crystal reflects the clockwise circularly polarized light of the light of the predetermined wavelength λ and transmits the counterclockwise circularly polarized light. Similarly, when the turning direction of the cholesteric liquid crystal is counterclockwise, the cholesteric liquid crystal reflects the counterclockwise circularly polarized light of the light of the predetermined wavelength λ and transmits the clockwise circularly polarized light.

When the helical pitch of the cholesteric liquid crystal is referred to as P, the refractive index of the liquid crystal molecules to extraordinary light is referred to as ne, and the refractive index of the liquid crystal molecules to ordinary light is referred to as no, a selective reflection range Δλ of the cholesteric liquid crystal to the perpendicularly incident light is generally referred to as “from no*P to ne*P”. Incidentally, in detail, the selective reflection range Δλ of the cholesteric liquid crystal changes to the range of “from no*P to ne*P” in accordance with the inclination angle φ of the reflective surface 321, the incident angle on the first boundary surface 317, and the like.

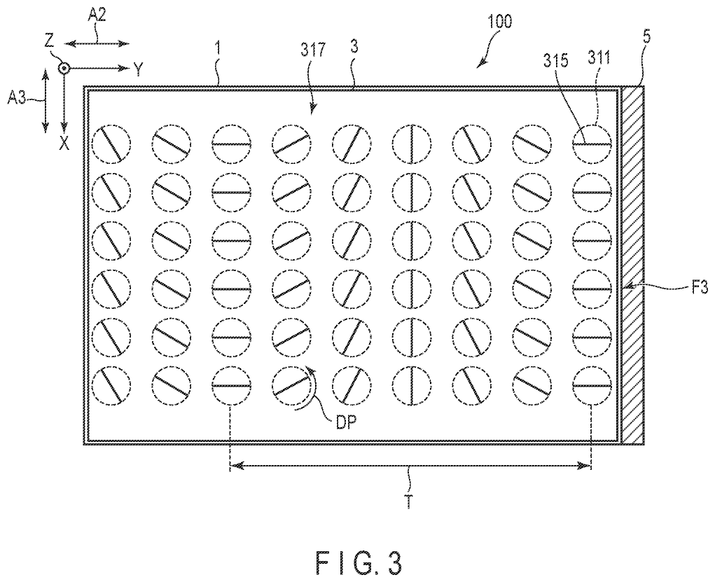

FIG. 3 is a plan view schematically showing the photovoltaic cell device 100.

FIG. 3 shows an example of the spatial phase of the helical structures 311. The spatial phase shown here is represented as the alignment direction of the element 315 located on the first boundary surface 317, of the element 315 included in the helical structure 311.

For each of the helical structures 311 arranged along the second direction A2, the alignment directions of the elements 315 located on the first boundary surface 317 are different from each other. In other words, the spatial phases of the helical structures 311 at the first boundary surface 317 are different along the second direction A2.

In contrast, the alignment directions of the elements 315 located on the first boundary surface 317 approximately match for each of the helical structures 311 arranged along the third direction A3. In other words, the spatial phases of the helical structures 311 on the first boundary surface 317 substantially match in the third direction A3.

In particular, when the helical structures 311 arranged in the second direction A2 are focused, the alignment directions of the respective elements 315 are different by a certain angle. In other words, the alignment directions of the plurality of the elements 315 arranged along the second direction A2 change linearly on the first boundary surface 317. Therefore, the spatial phases of the plurality of helical structures 311 arranged along the second direction A2 change linearly along the second direction A2. As a result, the reflective surface 321 inclined to the first boundary surface 317 and the optical waveguide 1 is formed, similarly to the optical element 3 shown in FIG. 2. In this example, “change linearly” indicates that, for example, the amount of change in the alignment direction of the element 315 is expressed by a linear function.

Incidentally, the alignment direction of the element 315 corresponds to the long axis direction of the liquid crystal molecule in the X-Y plane when the helical structure 311 is the cholesteric liquid crystal.

As shown in FIG. 3, the distance between the two helical structures 311 at the time when the alignment direction of the element 315 changes by 180 degrees along the second direction A2, on the first boundary surface 317, is defined as a period T of the helical structures 311. Incidentally, DP refers to the turning direction of the elements 315 in FIG. 3. The inclination angle φ of the reflective surface 321 shown in FIG. 2 is appropriately set by the period T and the helical pitch P.

When the helical structure 311 is the cholesteric liquid crystal, the optical element 3 is formed in the following manner. For example, the optical element 3 is formed by applying light to the plurality of liquid crystal molecules which are a plurality of elements 315 to polymerize the plurality of liquid crystal molecules. Alternatively, the optical element 3 is formed by controlling the alignment of the polymeric liquid crystal material in a liquid crystal state at a predetermined temperature or a predetermined concentration so as to form the plurality of helical structures 311, and then transferring the polymeric liquid crystal material to a solid while maintaining the alignment.

In the optical element 3, the adjacent helical structures 311 are combined with each other while maintaining the alignment of the helical structure 311, i.e., while maintaining the spatial phase of the helical structure 311, by polymerization or transfer to a solid. As a result, in the optical element 3, the alignment direction of each liquid crystal molecule is fixed.

A case where the helical pitch P of the cholesteric liquid crystal is adjusted such that the selective reflection range Δλ becomes the infrared ray will be described. From the viewpoint of increasing the reflectance of the optical element 3 on the reflective surface 321, the thickness of the optical element 3 along the first direction A1 is desirably set to be several to approximately ten times as large as the helical pitch P. In other words, the thickness of the optical element 3 is approximately 3 to 10 μm.

When a material is directly applied to the second main surface F2 of the optical waveguide 1 to form the optical element 3 which is in contact with the second main surface F2, a first tensile stress is generated on the first main surface F1 side of the optical waveguide 1 in accordance with shrinkage at the time when the applied material is cured. In particular, when a relatively thick optical element 3 having a thickness of 3 μm or more is directly formed on the optical waveguide 1, a larger first tensile stress is generated in the optical waveguide 1. Such a first tensile stress may contribute to warp of the optical waveguide 1.

Therefore, in Embodiment 1, the material is directly applied to the first main surface F1 of the optical waveguide 1 to form the protective film 10 which is in contact with the first main surface F1. Such a protective film 10 is a transparent organic film. In the process of forming the protective film 10, a second tensile stress is generated on the second main surface F2 side of the optical waveguide 1 in accordance with shrinkage at the time when the applied material is cured.

The magnitude of the second tensile stress generated on the second main surface F2 side is substantially equivalent to the magnitude of the first tensile stress generated on the first main surface F1 side. As a result, the warp of the optical waveguide 1 is suppressed. The reliability can be thereby improved.

In order to make the first tensile stress and the second tensile stress match, the protective film 10 is formed of, for example, the same material as the optical element 3, and is formed to have the same thickness as the optical element 3. In addition, the amount of shrinkage in the process of forming the protective film 10 is adjusted to be equivalent to the amount of shrinkage in the process of forming the optical element 3. In one example, the protective film 10 can be formed of an acrylic resin, a polyimide resin, or the like.

The first tensile stress and the second tensile stress do not need to completely match. From the viewpoint of suppressing the warp of the optical waveguide 1, the allowable value of the difference between the first tensile stress and the second tensile stress is calculated appropriately in accordance with the elasticity, thickness, installation area, volume, and the like of each of the optical waveguide 1, the optical element 3, and the protective film 10.

### Embodiment 2

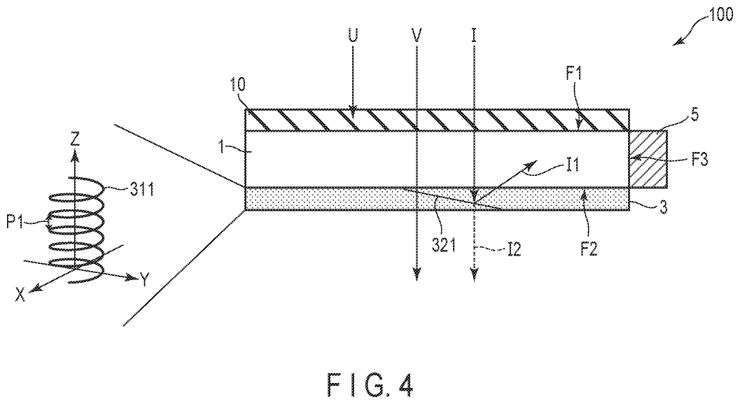

FIG. 4 is a cross-sectional view schematically showing a photovoltaic cell device 100 according to Embodiment 2. Embodiment 2 shown in FIG. 4 is different from Embodiment 1 described above in that a protective film 10 is an ultraviolet cut layer opposed to a first main surface F1.

Such a protective film 10 may be separately formed in a film shape and bonded to a first main surface F1 of an optical waveguide 1 or may be formed by directly applying the material to the first main surface F1 of the optical waveguide 1. The protective film 10 of Embodiment 2 may comprise a function of generating a second tensile stress described in Embodiment 1.

The optical element 3 contains cholesteric liquid crystal turning in one direction, as a helical structure 311. The cholesteric liquid crystal 311 in the optical element 3 is schematically shown. For example, the cholesteric liquid crystal 311 has a helical pitch P1 along the Z-direction to reflect the first circularly polarized light I1 of the infrared ray I as a selective reflection range. The helical pitch P1 of the cholesteric liquid crystal 311 is constant and hardly changes along the Z-direction.

When the solar light including the visible light V, the ultraviolet ray U, and the infrared ray I is made incident on the photovoltaic cell device 100 of Embodiment 2, the ultraviolet ray U of the solar light do not pass through the protective film 10. The protective film 10 serving as the ultraviolet cut layer may absorb the incident ultraviolet ray U or may reflect the ultraviolet ray U. Therefore, the arrival of the ultraviolet ray U to the optical waveguide 1 and the optical element 3 is suppressed. Degradation or coloring of the optical element 3 caused by the ultraviolet ray U can be thereby suppressed.

In contrast, the visible light V of the solar light passes through the protective film 10, the optical waveguide 1, and the optical element 3. In other words, the photovoltaic cell device 100 transmits each of the first component (blue component), the second component (green component), and the third component (red component) that are main components of the visible light V. For this reason, coloring of the light transmitted through the photovoltaic cell device 100 can be suppressed. In addition, reduction in the transmittance of the visible light V in the photovoltaic cell device 100 can be suppressed.

Furthermore, the infrared ray I of the solar light pass through the protective film 10 and the optical waveguide 1 to be made incident on the optical element 3. Then, the optical element 3 reflects the first circularly polarized light I1 of the infrared ray I toward the optical waveguide 1 and the photovoltaic cell 5, on the reflective surface 321. Incidentally, in Embodiment 2 described here, the optical element 3 transmits the second circularly polarized light I2 of the infrared ray I. The reflected first circularly polarized light I1 enters the inside the optical waveguide 1 from the second main surface F2, and propagates inside the optical waveguide 1 while repeatedly reflected in the optical waveguide 1. The photovoltaic cell 5 receives the infrared ray I emitted from a side surface F3 to generate electricity. In Embodiment 2, too, the photovoltaic cell 5 having a high absorption index of the infrared ray I as described in Embodiment 1 is desirably applied. As a result, electricity can be efficiently generated by using the infrared ray I.

According to Embodiment 2, deterioration and coloring of the optical element 3 caused by the ultraviolet ray U can be suppressed and the reliability can be improved.

### Embodiment 3

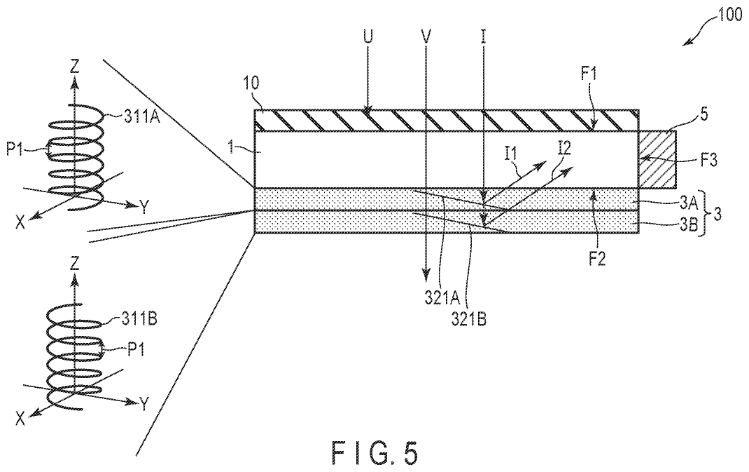

FIG. 5 is a cross-sectional view schematically showing a photovoltaic cell device 100 according to Embodiment 3. Embodiment 3 shown in FIG. 5 is different from Embodiment 2 shown in FIG. 4 in that an optical element 3 includes a first layer 3A containing cholesteric liquid crystal 311A turning in a first turning direction, and a second layer 3B containing cholesteric liquid crystal 311B turning in a second turning direction opposite to the first turning direction. The first layer 3A and the second layer 3B overlap in the Z-direction. The first layer 3A is located between the optical waveguide 1 and the second layer 3B.

The cholesteric liquid crystal 311A contained in the first layer 3A is configured to reflect first circularly polarized light of the first turning direction, of a selective reflection range. The cholesteric liquid crystal 311B contained in the second layer 3B is configured to reflect second circularly polarized light of the second turning direction, of the selective reflection range.

The cholesteric liquid crystals 311A and 311B both have helical pitches P1 along the Z-direction in order to reflect the infrared ray I as the selective reflection range, as enlarged and schematically shown. In other words, the helical pitches P1 of the respective cholesteric liquid crystal 311A and cholesteric liquid crystal 311B are equivalent to each other. As a result, the cholesteric liquid crystal 311A of the first layer 3A is configured to reflect first circularly polarized light I1 of the infrared ray I, and the cholesteric liquid crystal 311B of the second layer 3B is configured to reflect second circularly polarized light I2 of the infrared ray I.

In the photovoltaic cell device 100 of Embodiment 3, the ultraviolet ray U is cut by the protective film 10, and the visible light V is transmitted through the protective film 10, the optical waveguide 1, and the optical element 3, similarly to the photovoltaic cell device 100 of Embodiment 2.

In addition, the first circularly polarized light I1 of the infrared ray I is reflected toward the optical waveguide 1 and the photovoltaic cell 5, on a reflective surface 321A formed on the first layer 3A of the optical element 3. In addition, the second circularly polarized light I2 of the infrared ray is made incident on the second layer 3B after transmitted through the first layer 3A in the optical element 3, and is reflected toward the optical waveguide 1 and the photovoltaic cell 5, on a reflective surface 321B formed on the second layer 3B. The reflected first circularly polarized light I1 and The reflected second circularly polarized light I2 propagate inside the optical waveguide 1. The photovoltaic cell 5 receives the infrared ray I emitted from a side surface F3 to generate electricity.

According to such Embodiment 3, the same advantages as those of Embodiment 2 can be obtained. In addition, electricity can be generated with not only the first circularly polarized light I1 of the infrared ray I but also the second circularly polarized light I2. Moreover, the transmission of infrared ray I can be suppressed in the photovoltaic cell device 100.

### Embodiment 4

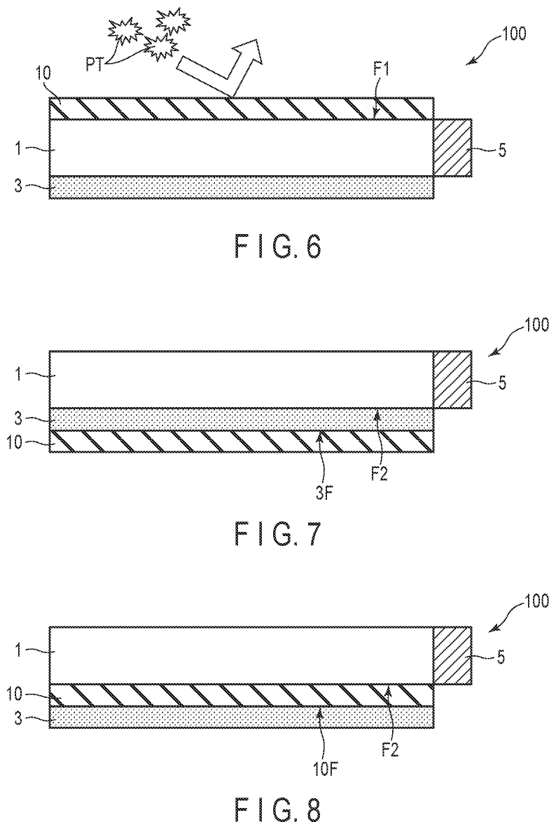

FIG. 6 is a cross-sectional view schematically showing a photovoltaic cell device 100 according to Embodiment 4. Embodiment 4 shown in FIG. 6 is different from Embodiment 1 described above in that a protective film 10 is an antifouling layer opposed to a first main surface F1.

The antifouling layer of Embodiment 4 is, for example, a photocatalyst layer that suppresses adhesion of a contaminant PT or decomposes the contaminant PT by being irradiated with the solar light (mainly, the ultraviolet ray). Such a photocatalyst layer is formed of, for example, titanium oxide, silver phosphate, or the like.

Alternatively, the antifouling layer of Embodiment 4 may be a catalyst layer which exerts catalysis without requiring the solar light. Such a catalyst layer is formed of, for example, titanium phosphate.

Furthermore, the antifouling layer of Embodiment 4 may be a water-repellent layer which suppresses the adhesion of water droplets. Such a water-repellent layer is formed of, for example, fluorine compounds.

Such a protective film 10 is formed by directly applying a material to a first main surface F1 of an optical waveguide 1, but may be separately formed in a film shape and bonded to the first main surface F1 of the optical waveguide 1. The protective film 10 may be in contact with the first main surface F1 or a transparent layer such as an adhesive layer may be interposed between the protective film 10 and the optical waveguide 1.

The protective film 10 of Embodiment 4 may comprise a function of generating a second tensile stress described in Embodiment 1.

According to Embodiment 4 thus described, contamination of the first main surface F1 of the optical waveguide 1 is suppressed and the reduction in power generation efficiency in the photovoltaic cell device 100 is suppressed. The reliability can be thereby improved.

### Embodiment 5

FIG. 7 is a cross-sectional view schematically showing a photovoltaic cell device 100 according to Embodiment 5. Embodiment 5 shown in FIG. 7 is different from Embodiment 1 described above in that a protective film 10 is opposed to a second main surface F2 and is in contact with an optical element 3. The optical element 3 is in contact with the second main surface F2 and is located between an optical waveguide 1 and the protective film 10.

As described in Embodiment 1, when a first tensile stress is generated in the optical waveguide 1 in the process of directly forming the optical element 3 on the second main surface F2, the protective film 10 is formed directly on a back surface 3F of the optical element 3 in Embodiment 5. Such a protective film 10 is, for example, a transparent inorganic film formed by chemical vapor deposition (CVD). In one example, the protective film 10 is formed of silicon oxide (SiOx), silicon nitride (SiNx), or the like.

In the process of forming the protective film 10, a compressive stress is generated on the optical element 3 side. In other words, the compressive stress generated in the process of forming the protective film 10 acts to cancel the first tensile stress generated in the process of forming the optical element 3. As a result, the warp of the optical waveguide 1 is suppressed. In addition, the inorganic protective film 10 formed of a material as exemplified has excellent water resistance and functions as a protective layer of the optical element 3. The reliability can be thereby improved.

### Embodiment 6

FIG. 8 is a cross-sectional view schematically showing a photovoltaic cell device 100 according to Embodiment 6. Embodiment 6 shown in FIG. 8 is different from Embodiment 5 described above in that a protective film 10 is located between an optical waveguide 1 and an optical element 3. From the viewpoint that the protective film 10 is in contact with the optical element 3, Embodiment 6 is the same as Embodiment 5. The protective film 10 is, for example, a transparent inorganic film, similarly to the protective film 10 of Embodiment 5.

The protective film 10 is in contact with a second main surface F2 of the optical waveguide 1. The optical element 3 is in contact with a back surface 10F of the protective film 10.

In such Embodiment 6, first, a compressive stress is generated in the optical waveguide 1 in the process of directly forming the protective film 10 on the second main surface F2 of the optical waveguide 1, and then a first tensile stress is generated on the protective film 10 side in the process of directly forming the optical element 3 on a back surface 10F of the protective film 10. The compressive stress and the first tensile stress act to cancel each other.

In such Embodiment 6, too, the same advantages as those of Embodiment 5 can be obtained.

### Embodiment 7

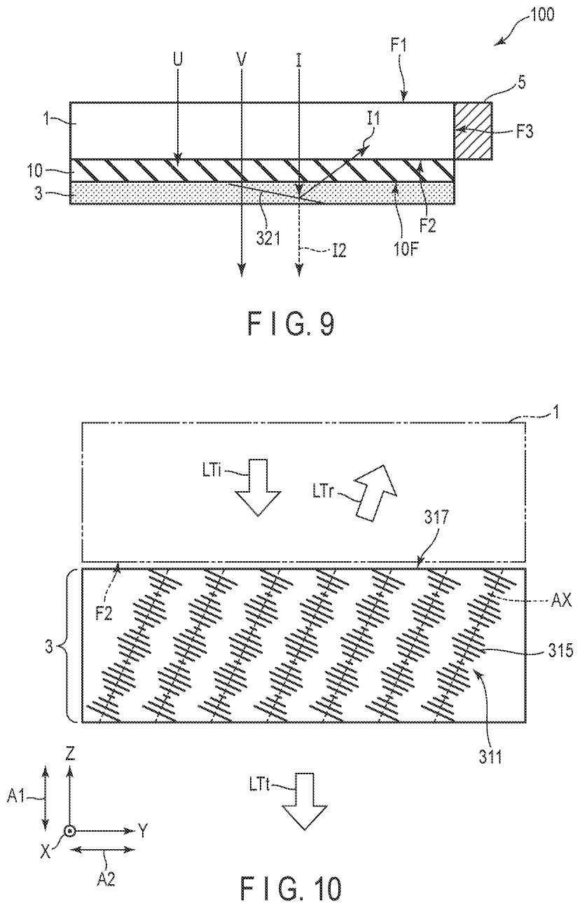

FIG. 9 is a cross-sectional view schematically showing a photovoltaic cell device 100 according to Embodiment 7. Embodiment 7 shown in FIG. 9 is different from Embodiment 6 described above in that a protective film 10 is an ultraviolet cut layer. The protective film 10 is located between an optical waveguide 1 and an optical element 3 and is in contact with a second main surface F2. The optical element 3 is in contact with a back surface 10F of the protective film 10.

When the protective film 10 is the ultraviolet cut layer, the protective film 10 may be in contact with a back surface 3F of the optical element 3, similarly to the protective film 10 of Embodiment 5 shown in FIG. 7.

Such a protective film 10 may be separately formed in a film shape and bonded to a second main surface F2 of an optical waveguide 1 or may be directly formed on the second main surface F2 of the optical waveguide 1. The protective film 10 of Embodiment 7 may comprise a function of generating a compressive stress described in Embodiment 6.

When the solar light including the visible light V, the ultraviolet ray U, and the infrared ray I is made incident on the photovoltaic cell device 100 of Embodiment 7, the ultraviolet ray U of the solar light are cut by the protective film 10 after passing through the optical waveguide 1. The protective film 10 serving as the ultraviolet cut layer may absorb the incident ultraviolet ray U or may reflect the ultraviolet ray U. Therefore, the arrival of the ultraviolet ray U to the optical element 3 is suppressed. Degradation or coloring of the optical element 3 caused by the ultraviolet ray U can be thereby suppressed.

In contrast, the visible light V of the solar light passes through the optical waveguide 1, protective film 10, and the optical element 3. In other words, the photovoltaic cell device 100 transmits each of the first component (blue component), the second component (green component), and the third component (red component) that are main components of the visible light V. For this reason, coloring of the light transmitted through the photovoltaic cell device 100 can be suppressed. In addition, reduction in the transmittance of the visible light V in the photovoltaic cell device 100 can be suppressed.

Furthermore, the infrared ray I of the solar light passes through the optical waveguide 1 and the protective film 10 and is made incident on the optical element 3. Then, the optical element 3 reflects first circularly polarized light I1 of the infrared ray I toward the optical waveguide 1 and the photovoltaic cell 5, on the reflective surface 321. In Embodiment 7 described here, the optical element 3 transmits second circularly polarized light I2 of the infrared ray I. The reflected first circularly polarized light I1 enters the inside the optical waveguide 1 from the second main surface F2, and propagates inside the optical waveguide 1 while repeatedly reflected in the optical waveguide 1. The photovoltaic cell 5 receives the infrared ray I emitted from a side surface F3 to generate electricity.

According to such Embodiment 7, deterioration and coloring of the optical element 3 caused by the ultraviolet ray U can be suppressed, and the reliability can be improved.

The optical elements 3 in above-described Embodiments 4 to 7 may reflect the first circularly polarized light I1 of the infrared ray I and transmit the second circularly polarized light I2 as described in Embodiment 2 or may reflect both the first circularly polarized light I1 and the second circularly polarized light I2 of the infrared ray I as described in Embodiment 3.

### Modification Example

FIG. 10 is a cross-sectional view schematically showing the optical element 3 according to a modified example.

The modified example shown in FIG. 10 is different from the optical element 3 described with reference to FIG. 2 in that the helical axes AX of the helical structures 311 are inclined to the optical waveguide 1 or the second main surface F2. In addition, in the current modified example, the spatial phases of the helical structures 311 on the first boundary surface 317 or in the X-Y plane are approximately coincident with each other. Besides, the helical structures 311 according to the modified example have the same characteristics as the helical structures 311 according to Embodiment 1 described above.

In such a modified example, the optical element 3 reflects light LTr which is part of the light LTi made incident via the optical waveguide 1 at a reflection angle corresponding to the inclination of the helical axes AX, and transmits the other light LTt.

The optical element 3 according to such a modified example can be applied as the optical elements 3 of Embodiments 1 to 7 described above.

As described above, according to the present embodiment, the photovoltaic cell device capable of increasing the reliability can be provided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A photovoltaic cell device comprising:
an optical waveguide including a first main surface, a second main surface opposed to the first main surface, and a side surface;
an optical element opposed to the second main surface, containing cholesteric liquid crystal, and reflecting at least a part of incident light via the optical waveguide toward the optical waveguide;
a photovoltaic cell opposed to the side surface; and
a protective film,
wherein the protective film is provided to be in contact with the first main surface.

2. The photovoltaic cell device of claim 1, wherein
the optical element is in contact with the second main surface, and
the protective film is a transparent organic film.

3. The photovoltaic cell device of claim 2, wherein
a refractive index of the protective film is equivalent to a refractive index of the optical waveguide.

4. The photovoltaic cell device of claim 1, wherein
the protective film is an ultraviolet cut layer or an antifouling layer.

5. The photovoltaic cell device of claim 1, wherein
the protective film is formed of a same material as the optical element.

6. The photovoltaic cell device of claim 1, wherein
the protective film has a thickness equivalent to the optical element.

7. A photovoltaic cell device comprising:
an optical waveguide including a first main surface, a second main surface opposed to the first main surface, and a side surface;
an optical element opposed to the second main surface, containing cholesteric liquid crystal, and reflecting at least a part of incident light via the optical waveguide toward the optical waveguide;
a photovoltaic cell opposed to the side surface; and
a protective film,
wherein the protective film is provided at a position opposed to the optical element.

8. The photovoltaic cell device of claim 7, wherein
the protective film is located between the optical waveguide and the optical element.

9. The photovoltaic cell device of claim 7, wherein
the optical element is located between the optical waveguide and the protective film.

10. The photovoltaic cell device of claim 8, wherein
the protective film is a transparent inorganic film which is in contact with the optical element.

11. The photovoltaic cell device of claim 9, wherein
the protective film is a transparent inorganic film which is in contact with the optical element.

12. The photovoltaic cell device of claim 8, wherein
the protective film is an ultraviolet cut layer.

13. The photovoltaic cell device of claim 9, wherein
the protective film is an ultraviolet cut layer.

14. The photovoltaic cell device of claim 1, wherein
the optical element reflects at least a part of infrared rays, and
the photovoltaic cell receives the infrared rays to generate electricity.

15. The photovoltaic cell device of claim 1, wherein
the photovoltaic cell comprises polycrystalline silicon.

16. The photovoltaic cell device of claim 1, wherein
the optical element comprises:
a first layer composed of the cholesteric liquid crystal; and
a second layer composed of the cholesteric liquid crystal,
the cholesteric liquid crystal of the first layer and the cholesteric liquid crystal of the second layer have equivalent helical pitches, and
the cholesteric liquid crystal of the first layer and the cholesteric liquid crystal of the second layer turn in an opposite direction each other.

17. The photovoltaic cell device of claim 7, wherein
the optical element reflects at least a part of infrared rays, and
the photovoltaic cell receives the infrared rays to generate electricity.

18. The photovoltaic cell device of claim 7, wherein
the photovoltaic cell comprises polycrystalline silicon.

19. The photovoltaic cell device of claim 7, wherein
the optical element comprises:
a first layer composed of the cholesteric liquid crystal; and
a second layer composed of the cholesteric liquid crystal,
the cholesteric liquid crystal of the first layer and the cholesteric liquid crystal of the second layer have equivalent helical pitches, and
the cholesteric liquid crystal of the first layer and the cholesteric liquid crystal of the second layer turn in an opposite direction each other.
